(19) United States
(12) Patent Application Publication
(10) Pub. No.: US 2016/0372711 A1
(43) Pub. Date: Dec. 22, 2016

(54) ORGANIC LIGHT-EMITTING DEVICE, METHOD FOR MANUFACTURING THE SAME, AND DISPLAY DEVICE

(71) Applicant: BOE TECHNOLOGY GROUP CO., LTD., Beijing (CN)

(72) Inventors: Yingying SONG, Beijing (CN); Ying CUI, Beijing (CN)

(73) Assignee: BOE TECHNOLOGY GROUP CO., LTD., Beijing (CN)

(21) Appl. No.: 14/763,129

(22) PCT Filed: Feb. 9, 2015
(86) PCT No.: PCT/CN2015/072519

§ 371 Date: Jul. 23, 2015

(30) Foreign Application Priority Data
Nov. 26, 2014 (CN) 201410696916.5

(51) Int. Cl. H01L 51/52; H01L 51/56

(52) U.S. Cl. CPC H01L 51/5271; H01L 51/5206; H01L 51/5234; H01L 51/5237; H01L 51/56

(57) ABSTRACT

The present disclosure provides an organic light-emitting device, a method for manufacturing the organic light-emitting device and a display device. The organic light-emitting device includes: a substrate; a light transmissible anode, an organic function layer and a light transmissible cathode configured to be formed on the substrate, wherein the organic function layer is provided between the anode and the cathode; and a reflection layer configured to be arranged on the substrate, wherein a surface of the reflection layer is configured to reflect lights and provided with a concave-convex part which bulges in a direction toward the organic function layer and concaves in a direction toward the substrate.

### CROSS REFERENCE OF RELATED APPLICATION

The present application claims the priority of Chinese patent application No. 201410696916.5 filed on Nov. 26, 2014, the disclosure of which is incorporated herein by reference.

### TECHNICAL FIELD

The present disclosure relates to a field of organic light emitting, and more particular to an organic light-emitting device, a method for manufacturing the organic light-emitting device and a display device.

### BACKGROUND

The technology of organic light emitting display (OLED) is widely recognized as a very promising flat panel display technology, which has many advantages such as (1) adopting organic materials as its raw material which is of a wide range of choices and may implement the display with any color in a range from blue to red; (2) illuminating in an all solid state with high brightness; (3) low drive voltage; (4) wide viewing angle being up to 160 degrees; (5) quick response being 1000 times faster than liquid crystal display (LCD); and (6) ultra thin and low power consumption.

The technology of OLED has been commonly used in a mobile communication terminal, a personal digital assistant (PDA), a handhold computer, and etc. A key part of the OLED is the organic light emitting device, which may be classified into a bottom emitting type and a top emitting type based on the emitting of lights.

FIG. 1 illustrates a section view of the bottom emitting type of the organic light emitting device, which includes, from top to bottom, a light transmissible cathode electrode layer 101, an organic function layer 102, a light transmissible anode electrode layer 103, a reflection layer 104, a protection layer 105, a dielectric layer 106, an insulation layer 107, a driving transistor 108 and a substrate 100, wherein the driving transistor 108 is provided between the dielectric layer 106 and the substrate 100.

Upon such organic light emitting device operates, a portion of the lights emitted by the organic function layer 20 may be reflected by the light transmissible cathode electrode layer 101, the organic function layer 102 itself, and the light transmissible anode electrode layer 103, and an effect of microcavity resonances may occur between the light transmissible cathode electrode layer 101 and the light transmissible anode electrode layer 103, which may cause a constructive interference and a destructive interference to be formed in the device by the lights emitted by the organic function layer 102, and thus the light with a particular wavelength is enhanced. As a result, a viewing angle of the device may be narrowed due to the difference among light intensities with different angles. In other words, the color of the light may varies due to the effect of the microcavity resonances if the organic light emitting device is viewed from different angles, i.e. a phenomenon of color cast occurs.

### SUMMARY

An object of the present disclosure is to provide an organic light-emitting device, a method for manufacturing the organic light-emitting device and a display device.

In one aspect, an organic light-emitting device includes: a substrate; a light transmissible anode, an organic function layer and a light transmissible cathode formed on the substrate, wherein the organic function layer is provided between the anode and the cathode; and a reflection layer configured to be arranged on the substrate, wherein a surface of the reflection layer is configured to reflect lights and provided with a concave-convex part which bulges in a direction toward the organic function layer and concaves in a direction toward the substrate.

In the organic light-emitting device according to the present disclosure, the concave-convex part includes a plurality of concave-convex units, and each of the concave-convex units includes at least one protuberance bulging in the direction toward the organic function layer.

In the organic light-emitting device according to the present disclosure, the concave-convex unit includes two opposite sides extending in the direction toward the organic function layer, wherein the two opposite sides are joined together and form the protuberance bulging in the direction toward the organic function layer, and one side of the protuberance and one side of a neighboring protuberance with the protuberance form a groove concaving in the direction toward the substrate.

In the organic light-emitting device according to the present disclosure, a distance H between a top of the protuberance and a bottom of the neighboring groove is in a range of 1 nm-1 μm, and a width L of a bottom of the protuberance is in a range of 0.1 μm-100 μm.

In the organic light-emitting device according to the present disclosure, a profile section of the protuberance along a direction of a width of the protuberance in the bottom and a profile section of the groove along a direction of a width of the groove on the top are in a shape of triangle, semi-ellipsoid or trapezoid.

In the organic light-emitting device according to the present disclosure, a material of the reflection layer is silver, copper, aluminum, magnesium, or metal alloy.

In the organic light-emitting device according to the present disclosure, an overcoat is provided on the substrate, and the reflection layer is covered by the overcoat.

In the organic light-emitting device according to the present disclosure, the overcoat includes a first portion provided under the reflection layer and a second portion provided above the reflection layer, and a material of the first portion and a material of the second portion are either same or different.

The display device according to the present disclosure includes the organic light-emitting device according to the present disclosure.

According to another aspect of the present disclosure, a method for manufacturing an organic light-emitting device includes:

forming a first film of an overcoat on a substrate, and then forming a first portion of the overcoat with a concave-convex pattern by embossing with a template;

forming a reflection layer on the first portion of the overcoat, wherein a surface of the reflection layer is configured to reflect lights and provided with a concave-convex part which bulges upwardly and concaves in a direction toward the substrate;

forming a second film of the overcoat on the reflection layer to obtain a second portion of the overcoat; and

forming a light transmissible anode, an organic function layer and a light transmissible cathode on the second portion of the overcoat, wherein the organic function layer is provided between the anode and the cathode.

In the technical solution of the present disclosure, for counteracting the color cast of the top emitting type of organic light-emitting device caused by the microcavity effect, it is provided a reflection layer including a concave-convex part which bulges in a direction to the organic function layer and concaves in a direction to the substrate. Different areas on the surface of the reflection layer for reflecting lights are of different heights, so that the lights reflected by the surface are with different path lengths. As a result, the color cast associated with different angles caused by the microcavity effect may be reduced because the reflected lights with different path lengths and the lights upwardly emitted by the organic function layer may compensate each other.

### BRIEF DESCRIPTION OF THE DRAWINGS

FIG. 1 illustrates a structure of an organic light-emitting device in prior art; and

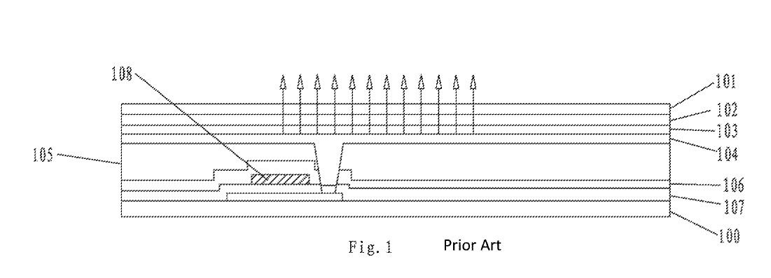

FIG. 2 illustrates a structure of an organic light-emitting device in the present disclosure.

### DETAILED DESCRIPTION

In the following, the present disclosure will be further explained in association with figures and specific embodiments to facilitate a person skilled in the art to further understand and implement the present disclosure, and such explanation is not intended to limit the scope of the present disclosure.

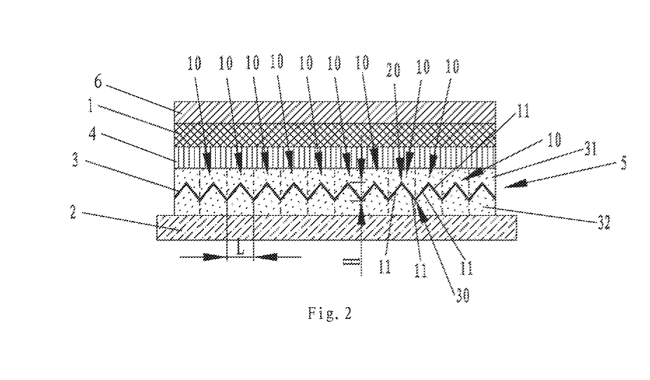

As illustrated in FIG. 2, the organic light-emitting device includes a substrate 2; a light transmissible anode, an organic function layer 1 for emitting lights and a light transmissible cathode being formed on the substrate 2, wherein the organic function layer 1 is provided between the anode and the cathode, and a reflection layer 3 for reflecting the lights is arranged on the substrate 2 and provided between the organic function layer 1 and the substrate 2, wherein on a surface of the reflection layer 3 for reflecting the lights, it is provided with a concave-convex part which bulges in a direction to the organic function layer 1 and concaves in a direction to the substrate 2.

Upon the organic light-emitting device starts to operate, the lights are irradiated on the reflection layer 3 through the organic function layer 1. Since the surface of the reflection layer 3 for reflecting the lights is provided with the concave-convex part which bulges in the direction to the organic function layer, the lights reflected by the reflection layer are with different path lengths. As a result, the color cast associated with different angles caused by the microcavity effect may be reduced because the reflected lights with different path lengths and the lights emitted upwardly by the organic function layer may compensate each other.

In the organic light-emitting device, the concave-convex part includes a plurality of concave-convex units 10, and each of the concave-convex units 10 includes at least one protuberance 20 bulging in the direction toward the organic function layer 1.

In the organic light-emitting device, the plurality of concave-convex units 10 are arranged either periodically or non periodically, and are of either an equal size or different sizes.

In the present disclosure, for counteracting the color cast of the top emitting type of organic light-emitting device caused by the microcavity effect, it is provided a reflection layer including a concave-convex part which bulges in a direction to the organic function layer and concaves in a direction to the substrate. Different areas on the surface of the reflection layer for reflecting lights are of different heights, so that the lights reflected by the surface are with different path lengths. As a result, the color cast associated with different angles caused by the microcavity effect may be reduced because the reflected lights with different path lengths and the lights upwardly emitted by the organic function layer may compensate each other.

In the organic light-emitting device, the concave-convex unit 10 includes two opposite sides 11 extending in the direction toward the organic function layer 1, wherein the two opposite sides 11 are joined together and form the protuberance 20 bulging in the direction toward the organic function layer 1, and one side 11 of the protuberance 20 and one side of a neighboring protuberance with the protuberance form a groove 30 concaving in the direction toward the substrate 2.

In the organic light-emitting device, an first included angle which is formed by the two opposite sides 11 of the concave-convex unit 10 and bulging in the direction toward the organic function layer 1 and an second included angle which is formed by one side 11 of the protuberance 20 and one side of the neighboring protuberance and concaving in the direction toward the substrate 2 may be of either same degrees or different degrees.

In the organic light-emitting device, a distance H between a top of the protuberance 20 and a bottom of the neighboring groove 30 is in a range of 1 nm-1 μm, and a width L of a bottom of the protuberance 20 is in a range of 0.1 μm-100 μm.

In the organic light-emitting device, a profile section of the protuberance 20 along a direction of a width of the protuberance in the bottom and a profile section of the groove 30 along a direction of a width of the groove on the top are in a shape of triangle.

In the organic light-emitting device of other embodiments, a profile section of the protuberance along a direction of a width of the protuberance in the bottom and a profile section of the groove along a direction of a width of the groove on the top may be in a shape of semi-ellipsoid or trapezoid.

In the organic light-emitting device, the material of the reflection layer 3 is silver, copper, aluminum, magnesium, or metal alloy.

In the organic light-emitting device, an overcoat 5 is provided on the substrate 2, and the reflection layer 3 is covered by the overcoat 5.

In the organic light-emitting device, the overcoat 5 includes a first portion 32 provided under the reflection layer 3 and a second portion 31 provided above the reflection layer 3, and the material of the first portion 32 and the material of the second portion 31 are either same or different.

In the organic light-emitting device, the material of the overcoat 5 may be SiO₂, SiNₓ or resin.

The display device according to the present disclosure includes the organic light-emitting device of the present disclosure. The display device may include an OLED panel, a mobile phone, a tablet computer, a television, a monitor, a notebook computer, a digital picture frame, a navigation system or any other product or part having a display function.

According to another aspect of the present disclosure, a method for manufacturing an organic light-emitting device includes:

forming a first film of an overcoat on a substrate, and then forming a first portion of the overcoat with a concave-convex pattern by embossing with a template;

forming a reflection layer on the first portion of the overcoat, wherein a surface of the reflection layer is configured to reflect lights and provided with a concave-convex part which bulges upwardly and concaves in a direction toward the substrate;

forming a second film of the overcoat on the reflection layer to obtain a second portion of the overcoat; and

forming a light transmissible anode, an organic function layer and a light transmissible cathode on the second portion of the overcoat, wherein the organic function layer is provided between the anode and the cathode.

In contrast to a conventional organic light-emitting device, in the organic light-emitting device of the present disclosure, different areas on the surface of the reflection layer for reflecting lights are of different heights, so that the lights reflected by the surface are with different path lengths. As a result, the color cast associated with different angles caused by the microcavity effect may be reduced because the lights with different path lengths and the lights emitted upwardly by the organic function layer may compensate each other

The optional embodiments of the present disclosure have been discussed. It is appreciated that many modifications and polishes may be made to the present disclosure without departing from the principle of the present disclosure for those skilled in the art. These modifications and polishes should also be deemed to be fallen within the scope of the present disclosure.

1. An organic light-emitting device comprising: a substrate; a light transmissible anode, an organic function layer and a light transmissible cathode formed on the substrate, wherein the organic function layer is provided between the anode and the cathode; and a reflection layer configured to be arranged on the substrate, wherein a surface of the reflection layer is configured to reflect lights and provided with a concave-convex part which bulges in a direction toward the organic function layer and concaves in a direction toward the substrate.

2. The organic light-emitting device according to claim 1, wherein the concave-convex part comprises a plurality of concave-convex units, and each of the concave-convex units comprises at least one protuberance bulging in the direction toward the organic function layer.

3. The organic light-emitting device according to claim 2, wherein the concave-convex unit comprises two opposite sides extending in the direction toward the organic function layer, wherein the two opposite sides are joined together and form the protuberance bulging in the direction toward the organic function layer, and one side of the protuberance and one side of a neighboring protuberance with the protuberance form a groove concaving in the direction toward the substrate.

4. The organic light-emitting device according to claim 3, wherein a distance between a top of the protuberance and a bottom of the neighboring groove is in a range of 1 nm-1 μm, and a width of a bottom of the protuberance is in a range of 0.1 μm-100 μm.

5. The organic light-emitting device according to claim 2, wherein a profile section of the protuberance along a direction of a width of the protuberance in the bottom and a profile section of the groove along a direction of a width of the groove on the top are in a shape of triangle, semi-ellipsoid or trapezoid.

6. The organic light-emitting device according to claim 1, wherein a material of the reflection layer is silver, copper, aluminum, magnesium, or metal alloy.

7. The organic light-emitting device according to claim 1, wherein an overcoat is provided on the substrate, and the reflection layer is covered by the overcoat.

8. The organic light-emitting device according to claim 7, wherein the overcoat comprises a first portion provided under the reflection layer and a second portion provided above the reflection layer, and a material of the first portion and a material of the second portion are either same or different.

9. A display device comprising the organic light-emitting device according to claim 1.

10. A method for manufacturing an organic light-emitting device comprising:
forming a first film of an overcoat on a substrate, and then forming a first portion of the overcoat with a concave-convex pattern by embossing with a template;
forming a reflection layer on the first portion of the overcoat, wherein a surface of the reflection layer is configured to reflect lights and provided with a concave-convex part which bulges upwardly and concaves in a direction toward the substrate;
forming a second film of the overcoat on the reflection layer to obtain a second portion of the overcoat; and
forming a light transmissible anode, an organic function layer and a light transmissible cathode on the second portion of the overcoat, wherein the organic function layer is provided between the anode and the cathode.

11. The method according to claim 10, wherein the concave-convex part comprises a plurality of concave-convex units, and each of the concave-convex units comprises at least one protuberance bulging in the direction toward the organic function layer.

12. The method according to claim 11, wherein the concave-convex unit comprises two opposite sides extending in the direction toward the organic function layer, wherein the two opposite sides are joined together and form the protuberance bulging in the direction toward the organic function layer, and one side of the protuberance and one side of a neighboring protuberance with the protuberance form a groove concaving in the direction toward the substrate.

13. The method according to claim 12, wherein a distance between a top of the protuberance and a bottom of the neighboring groove is in a range of 1 nm-1 μm, and a width of a bottom of the protuberance is in a range of 0.1 μm-100 μm.

14. The method according to claim 11, wherein a profile section of the protuberance along a direction of a width of the protuberance in the bottom and a profile section of the groove along a direction of a width of the groove on the top are in a shape of triangle, semi-ellipsoid or trapezoid.

15. The method according to claim 10, wherein a material of the reflection layer is silver, copper, aluminum, magnesium, or metal alloy.

16. The method according to claim 10, wherein an overcoat is provided on the substrate, and the reflection layer is covered by the overcoat.

17. The method according to claim 16, wherein the overcoat comprises a first portion provided under the reflection layer and a second portion provided above the reflection layer, and a material of the first portion and a material of the second portion are either same or different.

18. The method according to claim 11, wherein an overcoat is provided on the substrate, and the reflection layer is covered by the overcoat.

19. The method according to claim 12, wherein an overcoat is provided on the substrate, and the reflection layer is covered by the overcoat.

20. The method according to claim 13, wherein an overcoat is provided on the substrate, and the reflection layer is covered by the overcoat.
